(19) United States
(12) Patent Application Publication
(10) Pub. No.: US 2013/0015391 A1
(43) Pub. Date: Jan. 17, 2013

(54) METHOD FOR THE PREPARATION AT LOW TEMPERATURES OF FERROELECTRIC THIN FILMS, THE FERROELECTRIC THIN FILMS THUS OBTAINED AND THEIR APPLICATIONS

(71) Applicants: Paula Maria Lousada Silveirinha Vilarinho, Aveiro (PT); Aiying Wu, Aveiro (PT); Maria Lourdes Calzada, Coslada (ES); Ricardo Jimenez Rioboo, Las Rozas de Madrid (ES); Ignos Bretos, Madrid (ES)

(72) Inventors: Paula Maria Lousada Silveirinha Vilarinho, Aveiro (PT); Aiying Wu, Aveiro (PT); Maria Lourdes Calzada, Coslada (ES); Ricardo Jimenez Rioboo, Las Rozas de Madrid (ES); Ignos Bretos, Madrid (ES)

(73) Assignees: CONSEJO SUPERIOR DE INVERSITACIONES CIENTIFICAS, Madrid (ES); UNIVERSIDADE DE AVERIRO, Aveiro (PT)

(21) Appl. No.: 13/496,816

(22) PCT Filed: Dec. 11, 2009
(86) PCT No.: PCT/IB2009/055699

§ 371 Date: Sep. 28, 2012

(30) Foreign Application Priority Data
Sep. 18, 2009 (PT) 104751

(51) Int. Cl. H01L 41/22; H01L 41/18; B82Y 30/00; B82Y 40/00

(52) U.S. Cl. 252/62.9 PZ; 427/541; 977/773; 977/900; 977/755; 977/890

(57) ABSTRACT

A processing technology is for the fabrication at low temperatures of ferroelectric crystalline oxide thin films, among others PbZrₓTi₁₋ₓO₃ (PZT) (<400° C. for PZT) with ferroelectric properties appropriate for integration in devices. The method is also for the fabrication of ferroelectric thin films of bronze tungsten (A₂B₂O₆), perovskite (ABO₃), pyrochlore (A₂B₂O₇) and bismuth-layer (Bi₄Ti₃O₁₂) structures, in which A and B are mono, bi-, tri-, tetra- and pentavalent ions. The method is based on the combination of Seeded Diphasic Sol Gel (SDSG) precursors with Photo Chemical Solution Deposition (PCSD) methodology and comprises the main following steps: i) synthesis of a modified metal-organic precursor solution of the desired metal oxide composition with a large photo-sensitivity in the UV wavelength range; ii) preparation by a sol gel process of nanoparticles of the desired composition, similar or dissimilar to the crystalline compound to be obtained from the previous precursor sol; iii) dispersion of the crystalline nanoparticles in the precursor sol to prepare a stable and homogeneous sol-gel based suspension; iv) deposition of the previous suspension onto substrates; v) UV irradiation in air or oxygen of the deposited layer and further thermal treatment in air or oxygen of the irradiated layer at temperatures below 400° C. The method provides for the fabrication of polycrystalline ferroelectric, piezoelectric, pyroelectric and dielectric thin films, dense and without cracks with thickness above 50 nm and below 800 nm on single crystal, polycrystalline, amorphous, metallic and polymeric substrates at low temperatures and with optimised properties, being applicable in microelectronics and optics industries.

### FIELD OF INVENTION

This invention provides the manufacture of ferroelectric crystalline metal oxide thin films by means of a low cost chemical solution deposition method that involves the use of low thermal budgets.

Specifically, this invention is related to the production of ferroelectric polycrystalline thin films (<500 nm) on selected substrates (semiconductors, metals, polymers, etc), by the combination of the photochemical solution deposition technique (PCSD) and the seeded diphasic sol-gel process (SDSG). More particularly this invention is related to the disclosure of a technique for depositing polycrystalline ferroelectric thin films such as lead ziconate titanate (PbZr₁₋ₓTiₓO₃, PZT) (and others) on different substrates and with thickness higher than 100 nm and lower than 500 nm, at temperatures lower than 400° C. for integration with microelectronic and micromechanical devices, e.g. MEMS (Micro-Electro-Mechanical Systems), FRAM (Ferroelectric Random Access Memories) or DRAM (Dynamic Random Access Memories) and flexible microelectronics.

### SUMMARY OF THE INVENTION

The present invention provides a method of fabrication of ferroelectric crystalline metal oxide thin films with well-defined properties at crystallization temperatures lower than those referred in the literature using a chemical solution deposition approach and the combination of the two low temperature synthesis methods, previously developed separately by the inventors: the Photo Chemical Solution Deposition (PCSD) and the Seeded Diphasic Sol Gel (SDSG). The combination of the nucleation of the crystalline phase in the films at low temperatures, by the photo-activation of the precursors chemistry, in addition to the simultaneous promotion of the crystallization, by introducing nanocrystalline nucleus, allows the preparation of crystalline ferroelectric films at low temperature (<400° C.) with well-defined dielectric and ferroelectric response.

### STATE OF THE ART

Ferroelectric (FE) thin films (TF) have received wide attention because of their growing use in many applications in microelectronics devices [1,2]. Their high dielectric constants have been used in Dynamic Random Access Memories, DRAMs, the possibility of reverting the spontaneous polarization under the electric field has been employed in the fabrication of Non Volatile Ferroelectric Random Access Memories, NVFERAMs, MicroElectroMechanical Systems, MEMS, and NanoElectroMechanical Systems, NEMS make use of their piezoelectric activity, the pyroelectric response is the basis of infrared sensors, and more recently the tunability of the dielectric permittivity with the electric field is being exploited in tunable microwave devices [3].

The solid solution between lead titanate (PbTiO₃) and lead zirconate (PbZrO₃) (Pb(ZrₓTi₁₋ₓ)O₃), known as PZT, is presently the most commonly used compositional system for piezoelectric applications with a high technological interest. Within the so-called morphotropic phase boundary (MPB), that occurs for the composition of Pb(Zr_{0.52}Ti_{0.48})O₃ (PZT 52/48), PZT exhibits enhanced dielectric and piezoelectric properties [4]. It is believed that due to the 14 possible directions of polarisation (eight [111] directions for the rhombohedral phase and six [001] directions for the tetragonal phase) in MPB compositions the reorientation of the polar axis is facilitated and the electrical properties enhanced [5,6].

Film fabrication techniques can be divided into two general classes: physical vapour deposition (PVD) techniques and chemical deposition techniques, this including chemical vapour deposition (CVD) and chemical solution deposition (CSD). In the former, atoms from a source are transferred in a continuous and controlled manner under a vacuum atmosphere (>10⁻⁵ Torr) to the substrate, in which the nucleation and growth of the film occurs atomistically. Depending on how the particles (atoms or ions) are removed from the target, the following PVD techniques are considered: rf sputtering, ion beam sputtering, electron beam evaporation and laser ablation, among others. The former allows for careful control of film thickness and orientation, and compatibility with the semiconductor integrated circuit processing. The difficulty in controlling the stoichiometry of multicomponent films, the slow rates of deposition (normally around 1 Å/s), the need for high-temperature post-deposition crystallization annealing and the high cost related with equipment acquisition and maintenance are the main disadvantages of these methods [7].

Chemical methods allow higher deposition rates, good stoichiometry control, and the production of large area defect-free films when compared with the previous ones. Chemical vapour deposition (CVD) is very attractive for industrial manufacturing of conformal functional films. However, the expensive equipment, limited availability and toxicity of sources of precursors for functional materials restrict the use of this technology. On the other hand, chemical solution deposition (CSD) methods, specially sol-gel, have been increasingly used for the preparation of films of functional materials. CSD techniques do not require vacuum ambience, are cheaper and faster, allow for a good stoichiometry control and production of large area defect-free films with good properties, although the texture degree of the film is inferior to that of films prepared by PVD. Wet chemical methods entail the preparation of the solution, the deposition of the solution onto the substrate by dip- or spin-coating and the subsequent thermal treatment of the as-deposited amorphous layer to remove the organics and to achieve the crystallization and densification of the coatings. Wet processes comprise sol-gel, metalorganic decomposition (MOD), electrochemical reaction and hydrothermal routes [8-13].

The crystallization temperature of post deposition heat treatment is a key parameter in the preparation of FE films by CSD. Many of the perovskite thin films are crystallized at temperatures well above 600° C., which degrade underlying electronics, semiconductor substrate or their metallization layers. For example, the heat treatment temperature of fabrication of sol-gel PZT films is around 650° C. to insure good dielectric properties, which constitutes a major drawback for PZT films integration. The low temperature synthesis of FE TF is then of paramount significance and more recently it became even more important due to the promising applications that can be envisaged if FE TF will be compatible with low cost low melting temperature flexible and rigid metallic and polymeric substrates.

For several years now the low temperature synthesis of ferroelectric thin/thick films has been attempted with modifications at the ‘precursor/green state film level’ and at the ‘post deposition processing level’. Concerning the modifications at the ‘post deposition processing level’ the most widely used is processing under rapid thermal annealing (RTA), thus transferring to ferroelectric films a processing technology typical of the semiconductor industry [14,15]. RTA of lead-based perovskite films minimizes the formation of fluorite/pyrochlore intermediate phases, detrimental substrate/film interfaces or volatilization of lead. Also, it greatly reduces the thermal budget required for crystallization, although the required process temperatures are still too high for some applications [1,6]. In the mean time other alternative methods such as laser-assisted crystallisation [16-19] or laser lift-off [20] are being used for the preparation of FE TF. The first one makes use of the local heating generated by the laser for the crystallisation of the electroceramic layer. The last one implies the fabrication of the crystalline layer onto a UV-transparent host-substrate at a high temperature (1000° C.) and then a transference to the semiconductor substrate by UV laser radiation at a low temperature (˜100° C.). Extensive and uniform films are not obtained by these methods, which difficult their industrial utilization.

Within the first set of modifications (at the ‘precursor/green state film level’), the use of seed-layers and of excess of the volatile components (e.g. excess PbO in lead zirconate titanate (PZT) and lead-contained system; Bi₂O₃ in strontium bismuth tantalate (SBT) and bismuth-containing system) or the combination of both, are widely reported in the literature. By using a lead titanate (PT) seed layer, the perovskite crystallization temperature was reported to decrease from 600° C. to 550° C. for 15 min for PZT TF [21]. With a PT seeded layer plus 50 mol % excess PbO, a single perovskite phase of PZT (53/47) films was obtained on Pt/Ti/SiO₂/Si at 500° C. for 2 h [22]. Perovskite crystallization temperature of 440° C. for 100 min for PZT (30/70) films has also been reported and it is attributed to the formation of a PtₓPb interlayer [23]. By using 10% excess PbO and either a 10-nm PT or TiO₂ nucleation layer, perovskite crystallization at 400° C. for 5 min for PZT (30/70) and PLZT (5/30/70) has been reported [24]. Precursor solutions containing Bi₂SiO₅ with large molar ratios of this compound to the ferroelectric phase make possible the CSD crystallization of ferroelectric thin films at temperatures by 150-200° C. lower than those of the original ferroelectric layer [25]. Concomitantly, the control of the solution chemistry to increase the homogeneity at the molecular level and thus, reactivity of the precursor has been used for the preparation of ferroelectric thin films at low temperatures as well In this way, PZT crystalline thin films in the titanium rich part have been obtained at ˜450° C. for very long annealing times and at 550° C. in the MPB region; similarly lead-free films (e.g. SrBi₂Ta₂O₉) have been also prepared at ˜600° C.

In general, the ferroelectric response of the films prepared by these low temperature methods is very weak, clearly denoting the incipient degree of crystallization of the perovskite films, what supports the reported need to post heat treat the films at higher temperatures.

The PhotoChemical Solution Deposition (PCSD) is based on previous literature that reported the formation of light-sensitive materials by using sol-gel process combined with UV irradiation [28, 29]. Single oxide films such as Ta₂O₅, ZrO₂ or SiO₂ have been prepared by this method at relatively low temperatures [30]. In the case of ferroelectric multioxide films, UV irradiation of sol-gel deposited layers has been used for the photo-patterning of the films [32-35]. Recently, PCSD was used and exploited for the fabrication of lead titanate based perovskite thin films by the Spanish Group [36]. PCSD is based on the use of sol gel precursors sensitive to the UV light [37] and on the use of UV radiation sources of high intensity (excimers lamps) [38] to catalyse the chemical reactions within the precursors towards the oxide crystallization. The photo excitation of certain organic compounds present in the sol-gel precursor solutions favours a rapid dissociation of alquil group-oxygen, reducing the temperature of formation of metal-oxygen-metal (M-O-M) of the final oxide material. This PCSD technique is available at the Spanish group and for that the group designed and constructed a laboratory-scale equipment that consists of a UV excimer lamp, which is assembled with a IR heating system (UV-assisted Rapid Thermal Annealing). This irradiation system can be combined with thermal treatments of the films at low temperatures in a commercial RTA equipment. The design of this laboratory-scale equipment is based on a UV-assisted RTA processor (Qualiflow Therm.—Jipelec. www.jipelec.com) currently commercialised by Jipelec that was developed with the participation of the Spanish inventors, in the frame of the EU BRPR-CT98-0777 Project ‘Microfabrication with UltraViolet-Assisted Sol-gel Technology, MUVAST’. This processor is now used for the densification and crystallization of sol-gel, MOD (metallorganic deposition), CSD and MOCVD (metallorganic chemical vapour deposition) layers. Using PCSD, ferroelectric lead titanate (PbTiO₃, PT) and modified PT (lead substituted by alkaline earth or lanthanide cations) thin films were prepared at temperatures over 450° C. onto Si-based substrates [39-42]. This approach has not been used for the low-temperature fabrication of PZT or any other lead free multi-oxide ferroelectric thin films.

Alternatively, the Portuguese Group has reported pure perovskite phase formation in PZT (52/48) films at 410° C. for 30 h and 550° C. for 30 min by using seeded diphasic sol-gel (SDSG) precursors [43]. The crystallization kinetics of PZT (52/48) films was studied and the overall activation energy was reduced from 219 kJ/mol (unseeded) to 174 kJ/mol for 1 wt % seeded PZT film and to 146 kJ/mol for 5 wt % seeded films [44]. The early stage of crystallization, structure, and microstructural development and electrical properties have been systematically investigated in these FE TF heat-treated at low temperatures ˜400° C. [45-47]. In this methodology perovskite nanometric particles are dispersed in the amorphous precursor and will act as seeds to promote the nucleation of the perovskite phase in the thin films at low temperatures. Perovskite PZT monophasic thin films were synthesised at 410° C., when using 5 mol % of seeds (600-700° C. are regular temperatures to obtain single phase MPB PZT films without seeds) [46]. Concomitantly BST thin films were prepared by this technique at 600° C. as well, (700-800° C. are regular temperatures to obtain single phase BST without seeds) [48]. Due to the presence of nanometric particles, the kinetics of the phase crystallization is enhanced and the total activation energy for the perovskite phase formation was reduced, the multiple nucleation centers generated by the seeds change markedly the microstructure of the films and, as a consequence, improved their electrical properties. PZT thin films prepared at 430° C. by SDSG exhibit reasonable ferroelectric properties adequate for applications that require metallic or even polymeric substrates [45,46]. In comparison with non seeded films ferroelectric response was even obtained for BST seeded films prepared at a 650° C. via SDSG [48].

These two techniques, PCSD and SDSG, have been proved to be low cost approaches for the synthesis of FE TF at low temperatures, but the combination of these techniques for the preparation of thin films has not yet been tried. Indeed, the combination of the nucleation of the crystalline phase at low temperatures, for example by the modification of the precursors chemistry, with the simultaneous promotion of the crystallization, for example by introducing nanocrystalline nucleus looks highly promising, for a reliable integration of FE TF with semiconductor substrates at temperatures compatible with those used in the Si-technology [49], as well as with other low melting temperature substrates; e.g. polymers and metal, opening the possible use of oxide based ferroelectric materials on the emerging flexible microelectronics [50].

### REFERENCES

[1] Y. Arimoto and H. Ishiwara. Current status of ferroelectric random-access memory. MRS Bulletin, 2004, 29, 11, 823.
[2] S. Trolier-McKinstry, P. Muralt. Thin film piezoelectrics for MEMS. Journal of Electroceramics, 2004, 12(1-2), 7.
[3] N. Setter and D. Damjanovic, L. Eng, G. Fox, S. Gevorgian, S. Hong, A. Kingon, H. Kohlstedt, N.Y. Park, G. B. Stephenson, I. Stolitchnov, A. K. Taganstev, D. V. Taylor, T. Yamada, S. Streiffer. Ferroelectric thin films: Review of materials, properties, and applications. Journal of Applied Physics. 2006, 051606, 100.
[4] B. Jaffe, W. R. Jr. Cook, and H. Jaffe. Piezoelectric Ceramics. Academic Press, London, 1971.
[5] W. Cao and L. E. Cross. Theoretical model for the morphotropic phase boundary in lead zirconate-lead titanate solid solutions. Phys. Rev. B, 1993, 47, 4825.
[6] X. H. Du, J. Zheng, U. Belegundu and K. Uchino. Crystal orientation dependence of piezoelectric properties of lead zirconate titanate near the morphotropic phase boundary. Appl. Phys. Lett. 1998, 72, 2421.
[7] O. Auciello, C. M. Foster and R. Ramesh. Processing technologies for ferroelectric thin films and heterostructures. Annu. Rev. Mater. Sci. 1998, 28, 501.
[8] L. M. Sheppard. Advances in processing of ferroelectric thin films. Ceram. Bull. 1992, 71, 85.
[9] R. W. Schwartz, T. J. Boyle, S. J. Lockwood, M. B. Sinclair, D. Dimos and C. D. Buchheit. Sol-Gel Processing of PZT Thin-Films—A Review of the State-of-the-Art and Process Optimization Strategies. Integr. Ferroelectr. 1995, 7, 259.
[10] C. J. Brinker, A. J. Hurd, P. R. Schunk, G. C. Frye and C. S. Ashley. Review of Sol-Gel Thin-Film Formation. J. Non-Cryst. Solids, 1992, 147, 424.
[11] I. M. Reaney, D. V. Taylor and K. G. Brooks. Ferroelectric PZT thin films by sol-gel deposition. J. Sol-Gel Sci. Techn. 1998, 13, 813.
[12] C. J. Brinker and G. W. Scherer. Sol-gel science: the physics and chemistry of sol-gel processing. Academic Press, New York, 1990.
[13] B. A. Tuttle and R. W. Schwartz. Solution deposition of ferroelectric thin films. MRS Bulletin, 1996, 21, 49.
[14] T. Hori and H. Iwasaky. Improved hot-carrier immunity in submicrometer mosfets with reoxidized nitrided oxides prepared by rapid thermal-processing. IEEE Electron Device Letters, 1989, 10(2), 64.
[15] K. Uchiyama, K. Arita, Y. Shimada, S. Hayasi, E. Fujii, T. Otsuki, N. Solayappan, V. Joshi and C. A. Paz de Araujo. Low temperature crystallization of SrBi₂Ta₂ O₉ (SBT) films Integrated Ferroelectrics, 2000, 30, 103.
[16] S. S. N. Bharadwaja, T. Dechakupt, S. Trolier-Mckinstry. Excimer Laser Crystallized (Pb,La)(Zr,Ti)O₃ Thin Films, J. Am. Ceram. Soc., 2008, 91(5), 1580.
[17] R. Waser, S. H. Hoffman, O. Baldus, A. Schuster. Crystallization of ceramic layers especially electronic ceramic thin films for integration with microelectronic and micromechanical devices e.g. for Fe-Ram production. German Patent, WO9941212, 1999.
[18] S. D. Russell, D. A. Sexton. Annealing or patterning of thin film ferroelectric materials by laser beam in appropriate atmosphere. U.S. Pat. No. 5,310,990, 1994.
[19] J. Karasawa, V. Joshi, J. Karaswaw, K. Jumahi, J. Vikram. Manufacture of integrated circuits using thin film layered superlattice material having improved microstructure. Japanese Patent, JP2005505911, 2002.
[20] T. P. Comyn, T. Chakraborty, R. E. Miles, S. J. Milne, Characterization of laser-transferred bismuth ferrite lead titanate ferroelectric thick films, Appl. Phys. Letts., 2008, 93, 052909.
[21] C. K. Kwok and S. B. Desu. Low-temperature perovskite formation of lead zirconate titanate thin-films by a seeding process. J. Mater. Res. 1993, 8 (2), 339.
[22] H. Suzuki, T. Koizumi, Y. Kondo, S. Kaneko. Low-temperature processing of Pb(Zr_{0.53}Ti_{0.47})O₃ thin film from stable precursor sol. J. Eur. Ceram. Soc. 1999, 19, 1397.
[23] Z. Huang, Q. Zhang, R. W. Whatmore. Low temperature crystallization of lead zirconate titanate thin films by a sol-gel method. J. Appl. Phys. 1998, 85(10), 7355.
[24] M. Mandeljd, M. Kosec, B. Malic, Z. Samardzija. Low temperature processing of lanthanum doped PZT thin films. Integrated Ferroelectrics, 2000, 30, 149.
[25] T. Kijima, H. Ishiwara. Si-substituted ultrathin ferroelectric films. Jpn. J. Appl. Phys., 2002, 41(6B), L716.
[26] K. Kato. Low-Temperature Synthesis of SrBi2Ta2O9 Ferroelectric Thin Films through the Complex Alkoxide Method: Effects of Functional Group, Hydrolysis and Water Vapor Treatment. Jpn. J. Appl. Phys., 1998, 37, 5178.
[27] Y. Beppu, Y. Beppu, K. Sunahara, Liquid composition for forming ferroelectric thin film and process for producing ferroelectric thin film. US Patent, US11260209 (2007).
[28] H. Imai. Ultravioled (UV) radiation, in Sol-Gel Science and Technology. Processing characterization and applications. Vol. I Sol-gel processing, Chp. 27, pg. 639. Kluwer Academic Pub., Ed. by S. Sakka. New York, 2005.
[29] I. W. Boyd, J. Y. Zhang. Photoinduced growth of dielectrics with excimer lamps. Solid-State Electronics. 2001, 45, 1413.
[30] M. Brinkmann, V. Z. Chan, E. L. Thomas, V. Y. Lee, R. D. Miller, N. Hadjichristidis, A. Augeropoulos. Room temperature synthesis of a-SiO₂ thin films by UV-assisted ozonolysis of a polymer precursor. Chem. Mater., 2001, 13, 967.
[31] S. Maekawa, T. Ohishi. Evaluation of SiO₂ thin films prepared by sol-gel method using photoirradiation. J. Non-Cryst. Solids, 1994, 169, 207.
[32] Y. Nakao, T. Nakamura, A. Kamisawa, H. Takasu. Electrical properties of PZT thin films derived from sol-gel solution containing photo-sensitive water-generator. Proceedings of the 9th International Symposium on Applications of Ferroelectrics, ISAF'94. Ed. by R. K. Pandey, M. Liu and A. Safari. Pennsylvania—USA, 1994, 450.
[33] H. Uchida, N. Soyama, K. Kageyama, K. Ogi, M. L. Scott, J. D. Cuchiaro, L. D. MacMillan, C. A. Paz de Araujo. Characterisation of self-patterned SBT/SBNT thin films from photosensitive solutions. Integrated Ferroelectrics, 1997 18, 249.
[34] M. Azuma, L. D. McMillan, C. A. Paz de Araujo, M. C. Scott. UV radiation process for making electronic devices having low leakage-current and low polarization fatigue. U.S. Pat. No. 5,871,853, 1999.
[35] K. Kageyama, K. Ogi, N. Soyama, L. D. McMillan, C. A. Paz de Araujo, M. C. Scott. Photopatterning of thin film for use in integrated circuits. U.S. Pat. No. 5,942,376, 1999.
[36] M. L. Calzada, I. Bretos, R. Jiménez, H. Guillon, L. Pardo. Low-temperature processing of ferroelectric thin films compatible with silicon integrated circuit technology. Adv. Mater., 2004, 16(18), 1620.
[37] M. L. Calzada, A. González, R. Poyato, L. Pardo. Photo-sensitive sol-gel solutions for the low-temperature UV-assisted processing of PbTiO₃ based ferroelectric thin films. J. Mater. Chem., 2003, 13, 1451.
[38] R. E. Van de Leest. UV photo-annealing of thin sol-gel films. Appl. Surf. Sci., 1995, 86, 278.
[39] I. Bretos, R. Jiménez, J. García-López, L. Pardo, M. L. Calzada. Photochemical solution deposition of lead-based ferroelectric films: Avoiding the PbO-excess addition at last. Chem. Mater, 2008, 20(18), 5731.
[40] I. Bretos, R. Jiménez, E. Rodríguez-Castellón, J. García-López, M. L. Calzada. Heterostructure and compositional depth profile of low-temperature processed lead titanate based ferroelectric thin films prepared by photochemical solution deposition. Chem. Mater., 2008, 20(4), 1443.
[41] M. L. Calzada, I. Bretos, R. Jiménez, H. Guillon, J. Ricote, L. Pardo. Low-temperature ultraviolet sol-gel photoannealing processing of multifunctional lead-titanate-based thin films. J. Mater. Res., 2007, 22(7), 1824.
[42] L. Pardo, R. Poyato, A. González, M. L. Calzada, E. Lynch, S. O'Brien, P. V. Kelly, I. Stolichnov, H. Guillon. Ca and La-modified lead titanate sol-gel thin films by UV-assisted processing for piezoelectric sensors. Ferroelectrics, 2002, 267, 335.
[43] A. Wu, I. M. Miranda Salvado, P. M. Vilarinho, J. L. Baptista, Processing and seeding effects on crystallisation of PZT thin films from sol-gel method. J. Eur. Ceram. Soc. 1997, 17, 1443.
[44] A. Wu, P. M. Vilarinho, I. M. Miranda Salvado, J. L. Baptista, C. M. de Jesus, C. M., M. F. da Silva. Characterization of seeded sol-gel lead zirconate titanate thin films. J. Eur. Ceram. Soc. 1999, 19, 1403.
[45] A. Wu, P. M. Vilarinho, I. M. Reaney, I. M. Miranda Salvado, J. L. Baptista, Seeding effect on the fatigue behaviour of PZT thin films. Integr. Ferroelectr. 2000, 30, 261.
[46] A. Wu, P. M. Vilarinho, I. Miranda Salvado, J. L. Baptista, Z. Zhou, I. M. Reaney, A. R. Ramos, M. F. da Silva. Effect of lead zirconate titanate seeds on PtxPb formation during the pyrolysis of lead zirconate titanate thin films. J. Am. Ceram. Soc. 2002, 85 (3), 641.
[47] A. Wu, P. M. Vilarinho, I. Reaney, and I. M. Miranda Salvado, Early stages of crystallization of sol-gel-derived lead zirconate titanate thin films. Chem. Mater. 2003, 15, 1147.
[48] P. M. Vilarinho, A. Wu, J. Gao. ‘Processo de fabricação de filmes finos de titanato de estrôncio e bário a temperaturas baixas por sol gel e de elevada sintonabilidade da permitividade dieléctrica’. Portuguese Patent, 104048, 26 Apr. 2008.
[49] International Technology Roadmap for Semiconductors (ITRS), 2007 Edition, http://www.itrs.net/Links/20071TRS/Home2007.htm.
[50] M. Missayaka, H. Hara, N. Karaki, S. Ionue, H. Kawai, S. Nebashi. Technical obstacles to thin film transistor circuits on plastic. Jap. J. Appl. Phys., 2008, 47(6), 4430.

### RELATED PATENTS

1. Paula Maria Vilarinho, Aiying Wu, Jie Gao. Processo de fabricação de filmes finos de titanato de estrôncio e bário a temperaturas baixas por sol gel e de elevada sintonabilidade da permitividade dieléctrica. Portuguese Patent, 104048 (2008).
2. S. D. Russell, D. A. Sexton. Annealing or patterning of thin film ferroelectric materials by laser beam in appropriate atmosphere. U.S. Pat. No. 5,310,990 (1994).
3. J. Karasawa, V. Joshi, J. Karaswaw, K. Jumahi, J. Vikram. Manufacture of integrated circuits using thin film layered superlattice material having improved microstructure. Japanese Patent, JP2005505911 (2002).
4. M. Azuma, L. D. McMillan, C. A. Paz de Araujo, M. C. Scott. UV radiation process for making electronic devices having low leakage-current and low polarization fatigue. U.S. Pat. No. 5,871,853 (1999).
5. K. Kageyama, K. Ogi, N. Soyama, L. D. McMillan, C. A. Paz de Araujo, M. C. Scott. Photopatterning of thin film for use in integrated circuits. U.S. Pat. No. 5,942,376 (1999)
6. Y. Beppu, Y. Beppu, K. Sunahara, Liquid composition for forming ferroelectric thin film and process for producing ferroelectric thin film. US Patent, US11260209 (2007)
7. F. S. Hintermaier, C. Dehm, W. Hoenlein, P. C. Van Buskirk, J. F. Roeder, B. C. Hendrix, T. H. Baum, D. A. Desrochers. Low temperature chemical vapour deposition process for forming bismuth-containing ceramic films useful in ferroelectric memory devices. U.S. Pat. No. 6,303,391 (2001).

### OBJECT OF THE INVENTION

The object of this invention is:

A new processing technology to fabricate ferroelectric thin films at low temperatures, lower than 400° C. for the case of PZT thin films, with optimised ferroelectric response, and the ferroelectric thin films directly and indirectly obtained by this technology. This methodology involves the combination of Seeded Diphasic Sol-Gel (SDSG) precursors and PhotoChemical Solution Deposition (PCSD).

The development of a fabrication method of ferroelectric films at low temperatures is compatible with a wide range of non-refractory substrates (semiconductors, polycrystalline ceramics, glass, metal and polymers).

### BRIEF STATEMENT OF THE INVENTION

A processing technology for the fabrication at low temperatures of ferroelectric crystalline oxide thin films, among others PbZrₓTi₁₋ₓO₃ (PZT) (<400° C. for PZT) with ferroelectric properties appropriate for integration in devices is disclosed. The method is also valid for the fabrication of ferroelectric thin films of bronze tungsten (A₂B₂O₆), perovskite (ABO₃), pyrochlore (A₂B₂O₇) and bismuth-layer (Bi₄Ti₃O₁₂) structures, in which A and B are mono, bi-, tri-, tetra- and pentavalent ions. The method is based on the combination of SDSG precursors with PCSD methodology. This invention provides a method for the fabrication of polycrystalline ferroelectric, piezoelectric, pyroelectric and dielectric thin films, dense and without cracks with thickness above 50 nm and below 800 nm on single crystal, polycrystalline, amorphous, metallic and polymeric substrates at low temperatures and with optimised properties and it comprises the main following steps:

i) synthesis of a modified metal-organic precursor solution of the desired metal oxide composition with a large photo-sensitivity in the UV wavelength range;

ii) preparation by a sol gel process of nanoparticles of the desired composition, similar or dissimilar to the crystalline compound to be obtained from the previous precursor sol;

iii) dispersion by the use of a dispersant agent and ultrasonication of the former crystalline nanoparticles in the precursor sol to prepare a stable and homogeneous sol-gel based suspension;

iv) deposition of the previous suspension onto substrates by either dip, spin or spray process, followed by drying and partial pyrolysis with heat treatment;

v) UV irradiation in air or oxygen of the deposited layer and further thermal treatment in air or oxygen of the irradiated layer at temperatures below 400° C.;

vi) repeat iv) and v) to grow films with thickness between 50-1000 nm.

### DETAILED DESCRIPTION OF THE PREFERRED EMBODIMENTS

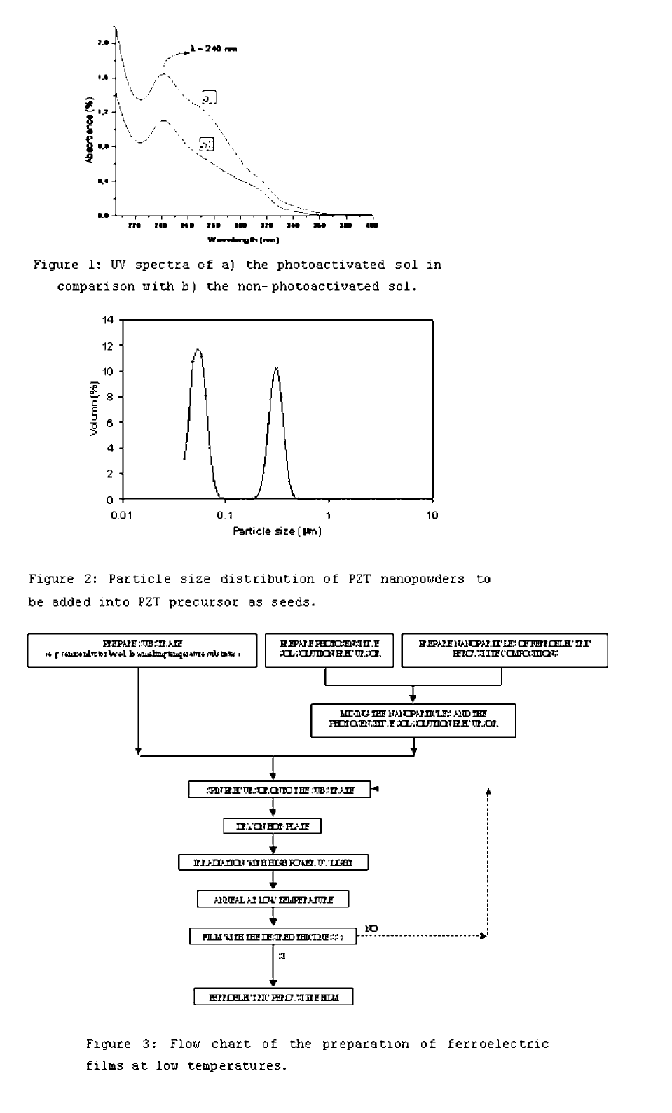

The method here disclosed comprises as a first step the preparation of a sol gel precursor of the required metallic elements and modified to make it UV sensitive. For that, the metal alkoxides of Ti(IV) and Zr(IV) are modified with a b-diketonate (e.g. acetylacetone, CH₃COCH₂COCH₃). These modified titanium and zirconium alkoxides are reacted with lead acetate in an alcoholic medium (e.g. ethanol, C₂H₅OH), obtaining the PZT sol precursor. This sol has an enhanced UV absorption, as shown in FIG. 1, thus proving its photosensitivity under UV light.

The preparation of nanoparticles of the required composition is the second part of the process. The nanoparticles may have the same or different composition from the precursor sol and are prepared by sol gel method. The particle size and particle size distribution is a critical parameter. FIG. 2 represents the particle size distribution of PZT nanoparticles.

These nanoparticles will be dispersed by ultrasonication in the photo-active sol to prepare a stable and homogeneous sol-gel based suspension. To guarantee an optimized dispersion, organic dispersants may be used. This suspension may be applied to any type of substrate by spray, spin or dip coating and followed by heat treatment cycles. The physical nature of the substrates may vary also from single crystals, polycrystalline, glass, metals to polymers, being such substrates preferably selected from the group consisting of platinized single crystal, Indium-Tin-Oxide ITO coated glass, low refractory metal foils, polymer plates, stainless steel and carbon steel plates, and polycrystalline ceramic substrates. Following each cycle of deposition, the coating is dried on a hot-plate, UV-irradiated and crystallized at temperatures below 400° C., using low thermal budgets that imply the use of RTA. Irradiation and crystallization may be carried out in air or oxygen. Deposition, drying, irradiation and crystallization are repeated until the required thickness is attained as schematically illustrated in FIG. 3.

Typical formulations are described below and it is emphasized that these formulations are not critical but may be widely varied to thin films of different dielectric materials to be used in microelectronic devices. PZT films processed by this method have the remnant polarization value of 5-15 m C/cm², and maximum polarization varying between 10 to 23 m C/cm², comparable to those of films processed by conventional methods at higher temperatures.

Besides the PZT composition, some examples of other film compositions that can be fabricated by the method herein disclosed include generally complex oxides of titanates, niobates, tantalates, zirconates, tungstates and bismuth based of the of bronze tungsten (A₂B₂O₆), perovskite (ABO₃), pyrochlore (A₂B₂O₇) and bismuth-layer (Bi₄Ti₃O₁₂) structures, in which A and B are mono, bi-, tri-, tetra- and pentavalent ions, to which this discovery is extended.

Preparation of the Metal Organic Based Sols

1. Photosensitive PbZr₁₋ₓTiₓO₃ Sols

As an example, a sol with x=0.48, PZT52/48, not containing any excess of lead.

Sols with an equivalent concentration of 0.2 moles of PbZr₁₋ₓTiₓO₃ per litre of liquid are synthesized by using as reagents commercial titanium bis-acetylacetonate diisopropoxide (Ti(OC₃H₇)₂(CH₃COCHCOCH₃)₂, zirconium tetra-isopropoxide (Zr(OC₃H₇)₄), lead acetate (Pb(CH₃CO₂)2.3H₂O and an alcoholic medium (ethanol, C₂H₅OH). Molar ratios of Ti/Zr/Pb of 0.48/0.52/1.00 are used. Acetylacetone (AcacH CH₃COCH₂COCH₃) is added to the Zr(OC₃H₇)₄ in a molar ratio of Zr/AcacH of 1/2. After heating, a transparent yellowish sol is obtained.

2. Preparation of the Sol Gel (Diphasic Sol)

PZT powders of nanometric dimensions are dispersed in ethanol. This suspension is added to the photosensitive PZT sol, previously prepared and this mixture is ultra-sonicated until a stable and homogeneous suspension is obtained. The particle size varies between 20 to 100 nm. And the weight percent of powders varies between 0 to 10% of the suspension weight.

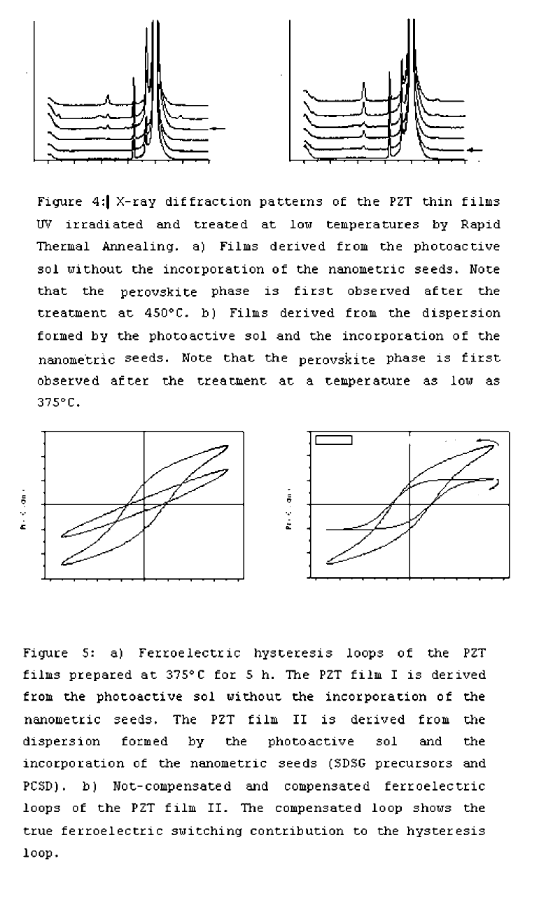

As a consequence of the combination of the role of the chemically modified precursors, responsible for the nucleation of the required crystalline phase at low temperatures with the role of the nanocrystalline particles to facilitate the nucleation and growth of the crystalline phase, the films heat treated at these very low temperatures (375° C. for the case of PZT films) exhibit a well developed degree of crystallinity as illustrated by the XRD patterns of FIG. 4. The PZT films prepared at a temperature as low as 375° C. have a well-defined ferroelectric response, as in comparison with the films prepared by each of the methodologies independently. FIG. 5 shows the ferroelectric loops measured in these films. This ferroelectric response is comparable to that reported for films of the same composition, but processed at temperatures higher than 600° C.

The disclosed methodology is applicable to microelectronics and optics industries to fabricate thin film capacitors for embedded applications, ferroelectric memories to substitute semiconductor memories, ferroelectric thin film wave guides and optic memory displays, surface acoustic wave substrates, pyroelectric sensors, microelectromechanical systems (MEMs), impact printer head as well as displacement transducers where low-cost and non-refractive substrate can be used for cost-effective products.

1. A method of producing ferroelectric thin films at low temperatures, comprising:
a) preparation of a base solution containing ferroelectric precursors with photosensitive complexes therein;
b) preparation of nano particles by solution process of ferroelectric compositions therein;
c) mixing perovskite nano powders with the photosensitive solution to obtain a well dispersed mixed suspension;
d) forming a thin layer by a solution deposition method concentration;
e) drying and ultraviolet (UV) irradiation of the deposited layer; and
f) rapid thermal annealing in air or oxygen rich atmosphere of the dried and irradiated layer at a temperature below 752° F. (400° C.), to convert an amorphous layer into a ferroelectric crystalline oxide thin film.

2. The method according to claim 1, wherein the base solution comprises photosensitive sol gel based solutions.

3. The method according to claim 1, wherein the solution deposition occurred by forming a thin layer by spinning or dipping the mixed suspension onto a substrate and where the layer comprises from about 0.5 to 10 weight percent of the perovskite nano powder and are about 100 nanometer or less in thickness, wherein the weight percentage is the metal concentration of the solution, and the layer has the same percentage.

4. The method according to claim 1, wherein the drying of the deposited layer being occurred on a hot-plate at 302° F. (150° C.) for less than 15 minutes and further exposure to ultraviolet irradiation in air or oxygen rich atmosphere and for a period of time from 1 to 5 hour, sufficient to evaporate and eliminate the majority of the organic species.

5. The method according to claim 1, wherein the synthesis of photosensitive solution precursors occurs by the modification of metal alkoxide reagents with β-diketonate compounds or other organic ligands.

6. The method according to claim 5, wherein the solutions comprising coordination complexes of transition metals, the complexes being photo-sensitive.

7. The method according to claim 6, wherein the mentioned complexes of metals are selected from the group of compositions consisting of derivates from titanium and zirconium alkoxides, or metal alkoxides modified with β-diketonate compounds or other organic ligands.

8. The method according to claim 7, wherein the base solutions comprise metal acetates, metal alkoxides and/or metal acetylactonates.

9. The method according to claim 8, wherein the metal acetates are dissolved in acetic acid.

10. The method according to claim 8, wherein the metal alkoxides are modified with acetylacetone.

11. The method according to claim 5, wherein the base solution containing glycols and alcohols as solvents and the element concentration are within the range 0.2-0.4M.

12. The method according to claim 1, wherein mixing the photosensitive sol-gel solution with up to about 10% weight of the ferroelectric nanoparticles selected from the group, with ferroelectric composition, wherein the particle size of the obtained ceramic powders is less than 100 nm, and produces a uniform stable dispersion.

13. The method according to claim 12, wherein the nanoparticles having a same crystalline phase and a same element composition of the sol-gel solution.

14. The method according to claim 10 wherein the nanopowders having a same or different crystalline phase and a different elemental composition of the sol-gel solution.

15. The method according to claim 11, wherein the nanoparticle compositions are selected from the group consisting of compositions having the same or different crystalline phase and different element composition, from the family of perovskite, pyrochlores and bismuth layer.

16. The method according to claim 15 wherein the nanoparticle compositions are compounds are selected from the group consisting of: BaₓSr₁₋ₓTiO₃, being x from [0 to 1], PbZrₓTi₁₋ₓO₃, being x from 0 to 1, CaTiO₃, MgTiO₃, NaₓTi₁₋ₓTiO₃ being x from 0 to 1, (1-x)K_{0.5}Na_{0.5}NbO₃ (KNN)-xLiTaO₃ being x from 0 to 1, Bi₄Ti₃O₁₂, among others.

17. The method according to claim 16, wherein the ceramic powders have a concentration comprised between 0.5 and 10 wt % of the solute in the sol precursor.

18. The method according to claim 17, comprising a further step of ultrasonic stirring, reducing agglomeration of particles.

19. The method according to claim 18, comprising a stirring step using an ultrasonic probe.

20. The method according to claim 15, comprising spraying, spinning or dipping of the stable mixed dispersion onto a substrate.

21. The method according to claim 20, wherein the substrates being selected from the group consisting of platinized single crystal, ITO coated glass, low refractory metal foils, polymer plates, stainless steel and carbon steel plates, and polycrystalline ceramic substrates.

22. The method according to claim 20, comprising a drying step, through heating the suspension derived film at a temperature up to 752° F. (400° C.), during 1 to 300 min.

23. The method according to claim 22, comprising a ultraviolet (UV) exposure through heating in air or oxygen rich atmosphere of the suspension derived film at a temperature up to 752° F. (400° C.) during 1 to 300 min.

24. The method according to claim 22, comprising a drying step using an ultrahigh-pressure mercury arc ultraviolet (UV) lamp.

25. The method according to claim 22, comprising a crystallization through heating the suspension derived film in air or oxygen rich atmosphere, at a temperature up to 752° F. (400° C.) during 1 to 300 min, and preferably using Rapid Thermal Annealing (RTA).

26. The method according to claim 1, wherein the repetition of steps from (c) to (e) producing crack-free polycrystalline films with thickness from 50 to 500 nm.

27. The method as claimed in claim 1, the method being applied to microelectronics and optics industries to fabricate thin film capacitors for embedded applications, ferroelectric memories to substitute semiconductor memories, ferroelectric thin film wave guides and optic memory displays, surface acoustic wave substrates, pyroelectric sensors, microelectromechanical systems (MEMs), impact printer head as well as displacement transducers where low-cost and non-refractive substrate can be used for cost-effective products.

28. PZT films directly processed by the method according to claim 1, wherein the films have remnant polarization value of 5-15 m C/cm², and maximum polarization varying between 10 to 23 m C/cm².
